(19) United States
(12) Patent Application Publication
(10) Pub. No.: US 2026/0051886 A1
(43) Pub. Date: Feb. 19, 2026

(54) SIGNAL RECEIVING CIRCUIT

(71) Applicant: Realtek Semiconductor Corp., HsinChu (TW)

(72) Inventor: Shih-Hsiung Huang, HsinChu (TW)

(73) Assignee: Realtek Semiconductor Corp., HsinChu (TW)

(21) Appl. No.: 19/281,774

(22) Filed: Jul. 28, 2025

(30) Foreign Application Priority Data
Aug. 19, 2024 (TW) 113131116

(51) Int. Cl. H03K 17/16

(52) U.S. Cl. CPC H03K 17/162

(57) ABSTRACT

A signal receiving circuit is provided. The signal receiving circuit includes an input transistor and a capacitor compensation circuit, where the capacitor compensation circuit is coupled to a gate terminal of the input transistor. The gate terminal of the input transistor is configured to receive an input signal, where a parasitic capacitance of the input transistor changes in response to a change in a voltage level of the input signal based on a first change direction. The capacitor compensation circuit is configured to provide a compensation capacitance according to the voltage level of the input signal, where the compensation capacitance changes in response to the change in the voltage level of the input signal based on a second change direction. More particularly, the first change direction is opposite to the second change direction.

### BACKGROUND OF THE INVENTION

### 1. Field of the Invention

The present invention is related to transistor circuits, and more particularly, to a signal receiving circuit (e.g. a source follower or an amplifier).

### 2. Description of the Prior Art

When a front-stage circuit transmits a signal to a back-stage circuit (such as a source follower or an amplifier), a driving capability of the front-stage circuit needs to be optimized based on a load (such as a capacitance) at an input of the back-stage circuit, in order to ensure that the signal can be correctly transmitted to the back-stage circuit without wasting power. The load of the input of the back-stage circuit may vary with a voltage level of the signal, however. The input of the back-stage circuit preferably receives a signal from the front-stage circuit without using additional metal-oxide-metal (MOM) capacitors or metal-insulator-metal (MIM) capacitors, especially in high-frequency applications, making the problem caused by load variation at the input of the back-stage circuit become non-negligible.

In addition, the amplifier may operate in an open-loop architecture in high-frequency applications wherein, in comparison with a closed-loop architecture, an input of the amplifier in the open-loop is not a virtual short circuit. This means that a voltage level of the input will vary greatly, resulting in load variation at the input of the amplifier.

Thus, there is a need for a novel architecture, which can minimize the load variation of the input of the source follower or the amplifier without introducing any side effect or in a way that is less likely to introduce side effects.

### SUMMARY OF THE INVENTION

An objective of the present invention is to provide a signal receiving circuit (e.g. a source follower or an amplifier), in order to solve the problem of the related art without introducing any side effect or in a way that is less likely to introduce side effects.

At least one embodiment of the present invention provides a signal receiving circuit. The signal receiving circuit comprises an input transistor and a capacitor compensation circuit, where the capacitor compensation circuit is coupled to a gate terminal of the input transistor. The gate terminal of the input transistor is configured to receive an input signal, where a parasitic capacitance of the input transistor changes in response to a change in a voltage level of the input signal based on a first change direction. The capacitor compensation circuit is configured to provide a compensation capacitance according to the voltage level of the input signal, where the compensation capacitance changes in response to the change in the voltage level of the input signal based on a second change direction. More particularly, the first change direction is opposite to the second change direction.

The embodiment of the present invention couples a circuit with an opposite capacitance change direction in parallel to an input terminal of the signal receiving circuit, to make changes in capacitances of both circuits cancel each other. As a result, a change in an overall capacitance of the input terminal of the signal receiving circuit can be minimized, thereby reducing power consumption requirements of a front-end circuit. In addition, the embodiment of the present invention will not greatly increase additional costs. Thus, the present invention can solve the problem of the related art without introducing any side effect or in a way that is less likely to introduce side effects.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a signal receiving circuit according to an embodiment of the present invention.

FIG. 2 is a diagram illustrating voltage-dependent capacitor compensation of two components which have opposite voltage-to-capacitance behaviors according to an embodiment of the present invention.

FIG. 3 is a diagram illustrating a signal receiving circuit according to an embodiment of the present invention.

FIG. 4 is a diagram illustrating a signal receiving circuit according to another embodiment of the present invention.

FIG. 5 is a diagram illustrating a signal receiving circuit according to another embodiment of the present invention.

FIG. 6 is a diagram illustrating voltage-dependent capacitor compensation of the same type of transistors according to an embodiment of the present invention.

FIG. 7 is a diagram illustrating a signal receiving circuit according to an embodiment of the present invention.

FIG. 8 is a diagram illustrating a sectional structure of an N-type transistor according to an embodiment of the present invention.

FIG. 9 is a diagram illustrating a sectional structure of an N-type varactor according to an embodiment of the present invention.

FIG. 10 is a diagram illustrating a signal receiving circuit according to another embodiment of the present invention.

### DETAILED DESCRIPTION

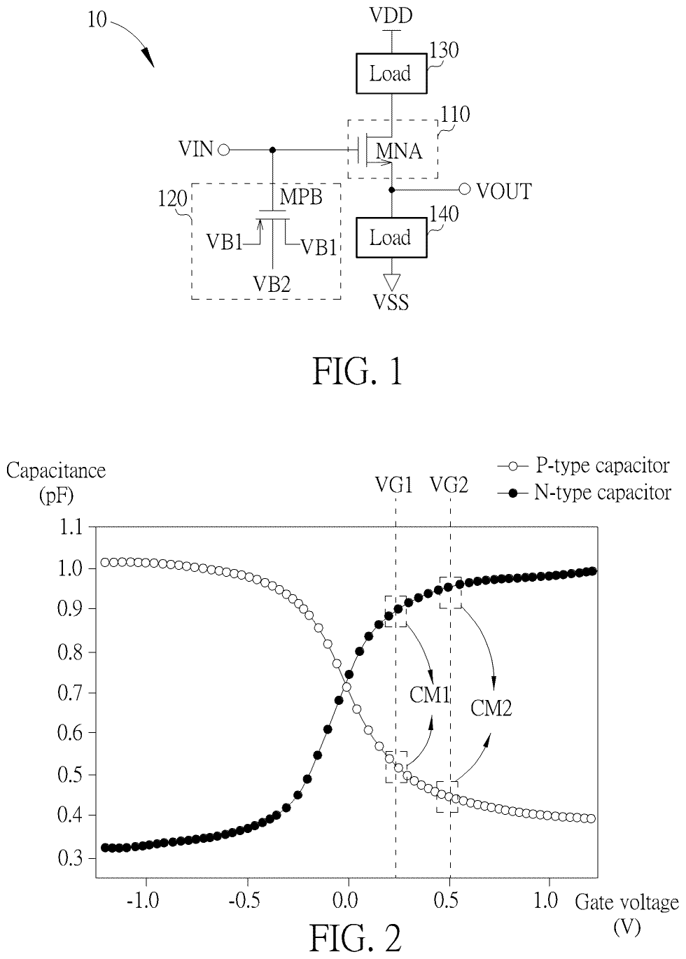

FIG. 1 is a diagram illustrating a signal receiving circuit 10 according to an embodiment of the present invention. As shown in FIG. 1, the signal receiving circuit 10 may comprise an input transistor 110 and a capacitor compensation circuit 120, where the capacitor compensation circuit 120 is coupled to a gate terminal of the input transistor 110. The gate terminal of the input transistor 110 is configured to receive an input signal VIN, where a parasitic capacitance of the input transistor 110 changes in response to a change in a voltage level of the input signal VIN based on a first change direction. In addition, the capacitor compensation circuit 120 is configured to provide a compensation capacitance according to the voltage level of the input signal VIN, where the compensation capacitance changes in response to the change in the voltage level of the input signal VIN based on a second change direction. More particularly, the first change direction is opposite to the second change direction. For example, the parasitic capacitance may increase in response to increase of the voltage level of the input signal VIN, and the compensation capacitance may decrease in response to increase of the voltage level of the input signal VIN, but the present invention is not limited thereto.

In this embodiment, the input transistor 110 is an N-type transistor such as MNA, and the capacitor compensation circuit 120 is a P-type transistor such as MPB, where a gate terminal of the P-type transistor MPB is coupled to a gate terminal of the N-type transistor MNA. In this embodiment, a source terminal and a drain terminal of the P-type transistor MPB are coupled to a bias voltage VB1, and a body terminal of the P-type transistor MPB is coupled to a bias voltage VB2. In some embodiments, the source terminal, the drain terminal and the body terminal of the P-type transistor MPB are coupled to bias voltages higher than the voltage level of the input signal VIN. For example, any (e.g. each) of the bias voltage VB1 and VB2 within the signal receiving circuit 10 may be a reference voltage VDD (e.g. a bias voltage with the highest voltage level in the signal receiving circuit 10). In another example, the bias voltage VB1 within the signal receiving circuit 10 may be the reference voltage VDD, and the bias voltage VB2 may be different from the reference voltage VDD in order to optimize the effect of voltage-dependent capacitor compensation. In this embodiment, the signal receiving circuit 10 may further comprise load circuits 130 and 140 (labeled “Load” in figures for brevity), where the load circuit 130 is coupled to a drain terminal of the N-type transistor MNA (e.g. coupled between the drain terminal of the N-type transistor MNA and the reference voltage VDD), and the load circuit 140 is coupled to a source terminal of the N-type transistor MNA (e.g. coupled between the source terminal of the N-type transistor MNA and a reference voltage VSS). In this embodiment, the signal receiving circuit 10 may be an N-type-input source follower, where the input transistor 110 may output an output signal VOUT on the source terminal of the N-type transistor MNA according to the input signal VIN.

FIG. 2 is a diagram illustrating voltage-dependent capacitor compensation of two components which have opposite voltage-to-capacitance behaviors according to an embodiment of the present invention, where hollow circle marks shown in FIG. 2 may represent capacitances of a P-type transistor (which is referred to as “P-type capacitor”) at different gate voltages, and solid circle marks shown in FIG. 2 may represent capacitances of an N-type transistor (which is referred to as “N-type capacitor”) at different gate voltages. As shown in FIG. 2, in a voltage dynamic range of the input signal VIN (e.g. 0V to 0.9V), the capacitance of the P-type transistor may decrease with increase of the gate voltage (e.g. the voltage level of the input signal VIN), and the capacitance of the N-type transistor may increase with increase of the gate voltage (e.g. the voltage level of the input signal VIN). Thus, when the P-type transistor and the N-type transistor are coupled in parallel, an effective capacitance which is less likely to vary with variation of the gate voltage can be obtained. For example, when the gate voltage is VG1, a sum of the capacitance of the P-type transistor and the capacitance of the N-type transistor (i.e. the effective capacitance of the P-type transistor and the N-type transistor coupled in series) may be CM1. When the gate voltage is increased to VG2, the capacitance of the P-type transistor is decreased and the capacitance of the N-type transistor is increased, and a sum CM2 of the capacitances of the P-type transistor and the N-type transistor may be equal or close to CM1.

Based on the above behaviors, a sum of the parasitic capacitance of the N-type transistor MNA and the compensation capacitance of the P-type transistor MPB within the signal receiving circuit 10 is less likely to vary with variation of the voltage level of the input signal VIN. In addition, properly designing a size of the capacitor compensation circuit 120 (e.g. a size of the P-type transistor MPB) and a voltage level of the bias voltage VB2 may further optimize the effect of cancelling variation of the parasitic capacitance and variation of the compensation capacitance. For example, adjusting the size of the capacitor compensation circuit 120 (e.g. the size of the P-type transistor MPB) can make a capacitance-voltage curve of the P-type capacitor shown in FIG. 2 be shifted upward or downward. In another example, adjusting the voltage level of the bias voltage VB2 (e.g. the voltage level of the body terminal of the P-type transistor MPB) can make the capacitance-voltage curve of the P-type capacitor shown in FIG. 2 be shifted leftward or rightward.

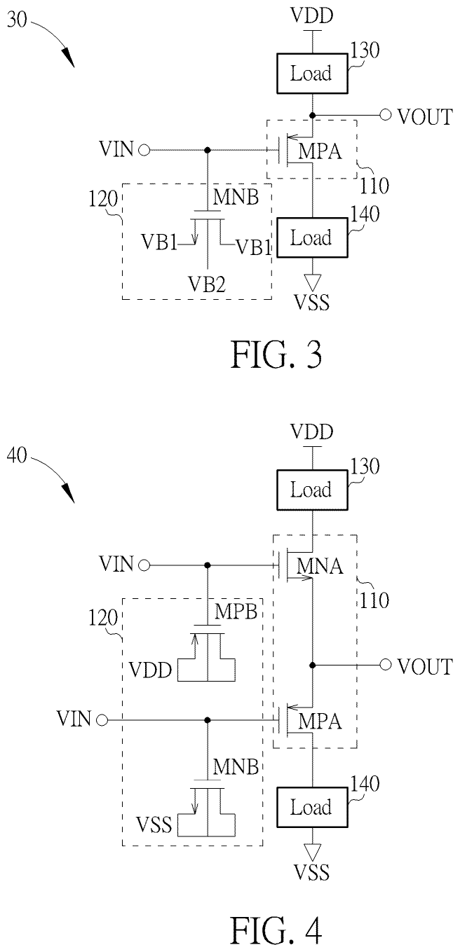

It should be noted that the input transistor 110 does not have to be implemented by the N-type transistor, and the capacitor compensation circuit 120 does not have to be implemented by the P-type transistor, as shown in FIG. 3. In the embodiment of FIG. 3, the input transistor 110 may be a P-type transistor such as MPA, and the capacitor compensation circuit 120 may be an N-type transistor such as MNB, where a gate terminal of the N-type transistor MNB is coupled to a gate terminal of the P-type transistor MPA. In this embodiment, a source terminal and a drain terminal of the N-type transistor MNB are coupled to the bias voltage VB1, and a body terminal of the N-type transistor MNB is coupled to the bias voltage VB2. In some embodiments, the source terminal, the drain terminal and the body terminal of the N-type transistor MNB are coupled to a bias voltage lower than the voltage level of the input signal VIN. For example, any (e.g. each) of the bias voltage VB1 and VB2 within a signal receiving circuit 30 may be the reference voltage VSS (e.g. a bias voltage having the lowest level in the signal receiving circuit 30, such as a ground voltage). In another example, the bias voltage VB1 within the signal receiving circuit 30 may be the reference voltage VSS, and the bias voltage VB2 may be different from the reference voltage VSS in order to optimize the effect of the voltage-dependent capacitor compensation. In this embodiment, the load circuit 130 is coupled to a source terminal of the P-type transistor MPA (e.g. coupled between the source terminal of the P-type transistor MPA and the reference voltage VDD), and the load circuit 140 is coupled to a drain terminal of the P-type transistor MPA (e.g. coupled between the drain terminal of the P-type transistor MPA and the reference voltage VSS). In this embodiment, the signal receiving circuit 30 may be a P-type-input source follower, where the P-type transistor MPA may output the output signal VOUT on the source terminal of the P-type transistor MPA according to the input signal VIN. Those skilled in this art can understand other details of the signal receiving circuit 30 according to the description of the signal receiving circuit 10 mentioned above, and related details are omitted here for brevity.

FIG. 4 is a diagram illustrating a signal receiving circuit 40 according to an embodiment of the present invention. In this embodiment, the input transistor 110 may comprise the N-type transistor MNA and the P-type transistor MPA, and the capacitor compensation circuit 120 may comprise the P-type transistor MPB and the N-type transistor MNB, where the gate terminal of the N-type transistor MNA and the gate terminal of the P-type transistor MPA are configured to receive the input signal VIN, the gate terminal of the P-type transistor MPB is coupled to the gate terminal of the N-type transistor MNA, and the gate terminal of the N-type transistor MNB is coupled to the gate terminal of the P-type transistor MPA. It should be noted that the source terminal, the drain terminal and the body terminal of the P-type transistor MPB within the signal receiving circuit 40 are coupled to the reference voltage VDD, and the source terminal, the drain terminal and the body terminal of the N-type transistor MNB within the signal receiving circuit 40 are coupled to the reference voltage VSS, but the present invention is not limited thereto. For example, the body terminal of the P-type transistor MPB may be coupled to a reference voltage other than the reference voltage VDD, and/or the body terminal of the N-type transistor MNB may be coupled to a reference voltage other than the reference voltage VSS. In this embodiment, the load circuit 130 is coupled to the drain terminal of the N-type transistor MNA (e.g. coupled between the drain terminal of the N-type transistor MNA and the reference voltage VDD), and the load circuit 140 is coupled to the drain terminal of the P-type transistor MPA (e.g. coupled between the drain terminal of the P-type transistor MPA and the reference voltage VSS). In this embodiment, the signal receiving circuit 40 may be a source follower which concurrently utilizes the N-type transistor MNA and the P-type transistor MPA to receive the input signal VIN, where the N-type transistor MNA and the P-type transistor MPA may output the output signal VOUT on the source terminals of the N-type transistor MNA and the P-type transistor MPA according to the input signal VIN. Those skilled in this art can understand other details of the signal receiving circuit 40 according to the description of the signal receiving circuit 10 mentioned above, and related details are omitted here for brevity.

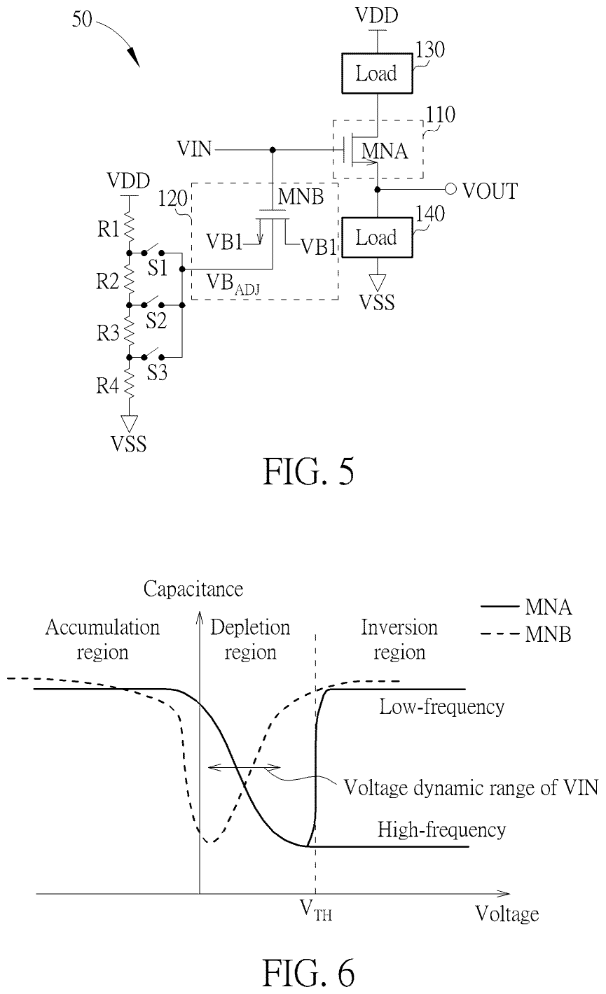

FIG. 5 is a diagram illustrating a signal receiving circuit 50 according to another embodiment of the present invention. In this embodiment, the input transistor 110 may be the N-type transistor MNA, and the capacitor compensation circuit 120 may be the N-type transistor MNB, where the gate terminal of the N-type transistor MNB is coupled to the gate terminal of the N-type transistor MNA, the source terminal and the drain terminal of the N-type transistor MNB are coupled to the bias voltage VB1, and the body terminal of the N-type transistor MNB is coupled to an adjusted voltage VB_{ADJ}. A shown in FIG. 5, the signal receiving circuit 50 may further comprise resistors R1, R2, R3 and R4 coupled in series to generate multiple resistive voltage division results, and switches S1, S2 and S3 are configured to select one of the multiple resistive voltage division results to be the adjustable voltage VB_{ADJ}. By turning on different switches (e.g. turning on the switch S1, S2 or S3) to adjust the voltage level of the body terminal of the N-type transistor MNB (e.g. the voltage level of the adjustable voltage VB_{ADJ}), a threshold voltage of the N-type transistor MNB can be adjusted to make the capacitance-voltage curve of the N-type transistor MNB be shifted leftward or rightward.

As shown in FIG. 6, the capacitance-voltage curve of each of the N-type transistors MNA and MNB comprises an interval of the capacitance increasing with increase of the gate voltage and an interval of the capacitance decreasing with increase of the gate voltage. Taking the N-type transistor MNA as an example, the N-type transistor MNA may have corresponding capacitance-voltage behaviors in an accumulation region, a depletion region and an inversion region (especially for high frequency and low frequency signals), where V_{TH} may represent a threshold voltage of the N-type transistor MNA. In this embodiment, as the capacitance of the N-type transistor MNA decreases with increase of the gate voltage in the voltage dynamic range of the input signal VIN, the interval of the capacitance increasing with increase of the gate voltage in the capacitance-voltage curve of the N-type transistor MNB can be shifted to the voltage dynamic range of the input signal VIN by controlling the adjustable voltage VB_{ADJ}, to make variation of an effective capacitance of the N-type transistor MNA and MNB in the voltage dynamic range of the input signal VIN be canceled or reduced. It should be noted that the capacitance-voltage behavior of each of the N-type transistors MNA and MNB in respective operation regions (e.g. the accumulation region, the depletion region and the inversion region) is not limited to that shown in FIG. 6. For example, a wafer foundry may change the capacitance-voltage behavior by adding or removing one or more manufacturing processes.

In some embodiments, the input transistor 110 may be a first P-type transistor, and the capacitor compensation circuit 120 may be a second P-type transistor. For example, the N-type transistor MNA within the signal receiving circuit 50 may be replaced with the P-type transistor MPA, and the N-type transistor MNB within the signal receiving circuit 50 may be replaced with the P-type transistor MPB, where the gate terminal of the P-type transistor MPB is coupled to the gate terminal of the P-type transistor MPA, and the body terminal of the P-type transistor MPB is coupled to the adjustable voltage VB_{ADJ}. Those skilled in this art can understand how to modify the architecture of the signal receiving circuit 50 to a version implemented by P-type transistors according to the descriptions related to the embodiments of FIG. 5 and FIG. 6, and related details are omitted here for brevity.

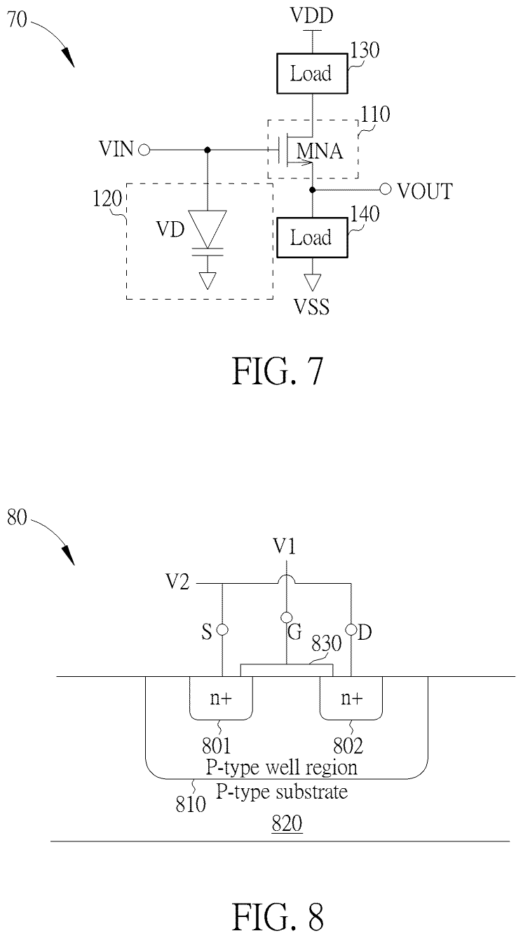

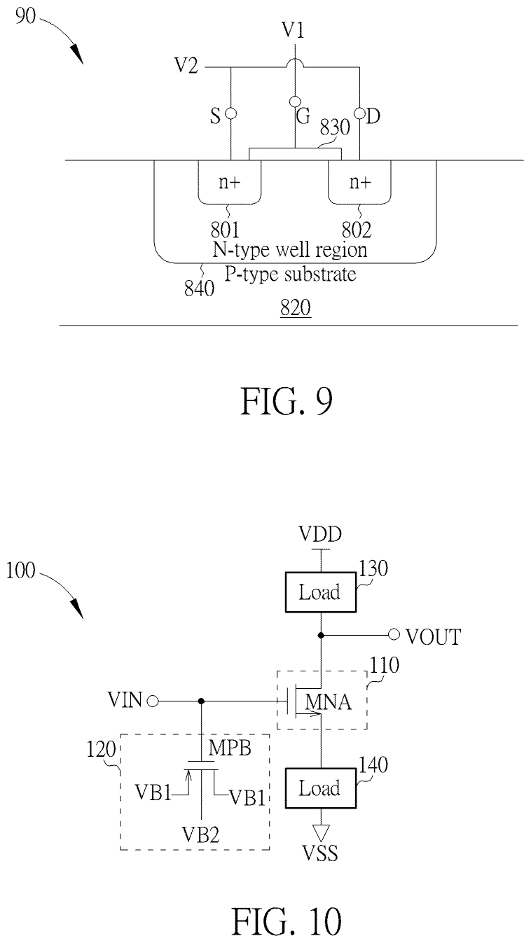

FIG. 7 is a diagram illustrating a signal receiving circuit 70 according to an embodiment of the present invention. In this embodiment, the input transistor 110 may be the N-type transistor MNA, and the capacitor compensation circuit 120 may be a varactor VD (e.g. an N-type varactor or a P-type varactor). In some embodiments, the input transistor 110 within the signal receiving circuit 70 may be the P-type transistor MPA, but the present invention is not limited thereto. For better comprehension of differences between the N-type transistor and the N-type varactor, please refer to FIG. 8 and FIG. 9, where FIG. 8 is a diagram illustrating a sectional structure of the N-type transistor 80 according to an embodiment of the present invention, and FIG. 9 is a diagram illustrating a sectional structure of the N-type varactor according to an embodiment of the present invention. As shown in FIG. 8, N-type heavily doped regions 801 and 802 within the N-type transistor 80 (e.g. labeled “n+” in figures for brevity) is on a P-type well region 810, and the P-type well region 810 is on a P-type substrate 820, where the N-type heavily doped regions 801 and 802 may be a source terminal (labeled “S” in figures for brevity) and a drain terminal (labeled “D” in figures for brevity) of the N-type transistor 80, respectively, and a gate-oxide layer 830 on a channel between the N-type heavily doped regions 801 and 802 may be a gate terminal (labeled “G” in figures for brevity) of the N-type transistor 80. In this embodiment, a voltage V2 coupled to the source terminal S and the drain terminal D of the N-type transistor 80 may be the bias voltage VB1 mentioned in the previous embodiment, and a voltage V1 coupled to the gate terminal G of the N-type transistor 80 may be the input signal VIN. In some embodiments, the N-type heavily doped regions 801 and 802 are on the P-type substrate 820, and the P-type well region 810 may be omitted.

In comparison with the N-type transistor 80, the N-type heavily doped regions 801 and 802 within the N-type varactor 90 shown in FIG. 9 is on an N-type well region 840, and the N-type well region 840 is on the P-type substrate 820. Other details of the N-type varactor 90 are the same as the N-type transistor 80, and are therefore omitted here for brevity. In addition, the varactor VD does not have to be implemented by the N-type varactor 90. In some embodiments, the varactor VD may be implemented by the P-type varactor, where those skilled in this art should understand differences between the P-type varactor and the P-type transistor according to the above descriptions, and related details are omitted here for brevity.

As the N-type transistor MNB, the P-type transistor MPB and the varactor VD have the behavior of having different capacitances in response to different voltage levels, all of them may be utilized for implementing the capacitor compensation circuit 120 in order to make an effective capacitance of an input terminal (e.g. the gate terminal of the input transistor 110) of a signal receiving circuit (e.g. the signal receiving circuits 10, 30, 40, 50 and 70) be less likely to change with the change in the voltage level of the input signal VIN. It should be noted that implementation of the capacitor compensation circuit 120 is not limited to the above components. As long as a component can have different capacitances in response to different voltage levels, this component may be utilized to implement the capacitor compensation circuit 120.

In addition, the above receiving circuits are illustrated based on implementation of a source follower, but the present invention is not limited thereto, where the design of utilizing the capacitor compensation circuit 120 to cancel the voltage-dependent capacitance of the input transistor 110 may be applied to an amplifier circuit. FIG. 10 is a diagram illustrating a signal receiving circuit 100 according to an embodiment of the present invention. As shown in FIG. 10, similar to the signal receiving circuit 10, the signal receiving circuit 100 may comprise the input transistor 110 (e.g. the N-type transistor MNA), the capacitor compensation circuit 120 (e.g. the P-type transistor MPB), and the load circuits 130 and 140, where the load circuit 130 is coupled to the drain terminal of the N-type transistor MNA (e.g. coupled between the drain terminal of the N-type transistor MNA and the reference voltage VDD), and the load circuit 140 is coupled to the source terminal of the N-type transistor MNA (e.g. coupled between the source terminal of the N-type transistor MNA and the reference voltage VSS). In comparison with the signal receiving circuit 10, the input transistor 110 (e.g. the N-type transistor MNA) within the signal receiving circuit 100 may output the output signal VOUT on the drain terminal of the input transistor 110 (e.g. the N-type transistor MNA) according to the input signal VIN, and the remaining details are the same as the signal receiving circuit 10.

Deduced by analogy, when the signal receiving circuit 30 shown in FIG. 3 outputs the output signal VOUT via the drain terminal of the P-type transistor MPA, the signal receiving circuit 30 may operate as an amplifier circuit. When the signal receiving circuit 40 shown in FIG. 4 outputs the output signal VOUT via the drain terminal of the N-type transistor MNA and the drain terminal of the P-type transistor MPA, the signal receiving circuit 40 may operate as an amplifier circuit. When the signal receiving circuit 50 shown in FIG. 5 outputs the output signal VOUT via the drain terminal of the N-type transistor MNA, the signal receiving circuit 50 may operate as an amplifier circuit. When the signal receiving circuit 70 shown in FIG. 7 outputs the output signal VOUT via the drain terminal of the N-type transistor MNA, the signal receiving circuit 70 may operate as an amplifier circuit.

In addition, the signal receiving circuits mentioned above (e.g. the signal receiving circuits 10, 30, 40, 50, 70 and 100) are illustrated based on a single-ended circuit architecture, but the present invention is not limited thereto. Each of the signal receiving circuits 10, 30, 40, 50, 70 and 100 may be regarded as a half-circuit of a differential source follower or a differential amplifier circuit, where each of the differential source follower and the differential amplifier circuit may comprise two identical and symmetric structures of the signal receiving circuits 10, 30, 40, 50, 70 or 100. Those skilled in this art should understand how to implement a differential circuit version of each of the signal receiving circuits 10, 30, 40, 50, 70 and 100 according to the above descriptions, and related details are omitted here for brevity.

To summarize, the voltage-dependent capacitance of the input transistor within the source follower or the amplifier circuit provided by the embodiments of the present invention can be compensated by utilizing the capacitor compensation circuit which has the opposite capacitance-changing direction to reduce variation of an overall capacitance, and thereby reduce power consumption requirements of a front-end circuit. In addition, the embodiments of the present invention will not greatly increase additional costs. Thus, the present invention can solve the problem of the related art without introducing any side effect or in a way that is less likely to introduce side effects.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A signal receiving circuit, comprising:
an input transistor, wherein a gate terminal of the input transistor is configured to receive an input signal, and a parasitic capacitance of the input transistor changes in response to a change in a voltage level of the input signal based on a first change direction; and
a capacitor compensation circuit, coupled to the gate terminal of the input transistor, configured to provide a compensation capacitance according to the voltage level of the input signal, wherein the compensation capacitance changes in response to the change in the voltage level of the input signal based on a second change direction;
wherein the first change direction is opposite to the second change direction.

2. The signal receiving circuit of claim 1, wherein the input transistor is an N-type transistor, the capacitor compensation circuit is a P-type transistor, and a gate terminal of the P-type transistor is coupled to a gate terminal of the N-type transistor.

3. The signal receiving circuit of claim 2, wherein a source terminal, a drain terminal and a body terminal of the P-type transistor are coupled to a bias voltage higher than the voltage level of the input signal.

4. The signal receiving circuit of claim 1, wherein the input transistor is a P-type transistor, the capacitor compensation circuit is an N-type transistor, and a gate terminal of the N-type transistor is coupled to a gate terminal of the P-type transistor.

5. The signal receiving circuit of claim 4, wherein a source terminal, a drain terminal and a body terminal of the N-type transistor are coupled to a bias voltage lower than the voltage level of the input signal.

6. The signal receiving circuit of claim 1, wherein the input transistor is a first N-type transistor, the capacitor compensation circuit is a second N-type transistor, a gate terminal of the second N-type transistor is coupled to a gate terminal of the first N-type transistor, and a body terminal of the second N-type transistor is coupled to an adjustable voltage.

7. The signal receiving circuit of claim 1, wherein the input transistor is a first P-type transistor, the capacitor compensation circuit is a second P-type transistor, a gate terminal of the second P-type transistor is coupled to a gate terminal of the first P-type transistor, and a body terminal of the second P-type transistor is coupled to an adjustable voltage.

8. The signal receiving circuit of claim 1, wherein the capacitor compensation circuit is a varactor.

9. The signal receiving circuit of claim 1, further comprising:
a load circuit, coupled to a source terminal of the input transistor;
wherein the input transistor outputs an output signal on the source terminal of the input transistor according to the input signal.

10. The signal receiving circuit of claim 1, further comprising:
a load circuit, coupled to a drain terminal of the input transistor;
wherein the input transistor outputs an output signal on the drain terminal of the input transistor according to the input signal.
